(19) United States
(12) Patent Application Publication
(10) Pub. No.: US 2021/0242053 A1
(43) Pub. Date: Aug. 5, 2021

(54) CERAMIC HEATER

(71) Applicant: NGK INSULATORS, LTD., Nagoya-City (JP)

(72) Inventors: Ryohei MATSUSHITA, Yokkaichi-City (JP); Shuichiro MOTOYAMA, Nagoya-City (JP)

(73) Assignee: NGK INSULATORS, LTD., Nagoya-City (JP)

(21) Appl. No.: 17/111,714

(22) Filed: Dec. 4, 2020

(30) Foreign Application Priority Data
Feb. 3, 2020 (JP) 2020-016116

(51) Int. Cl. H01L 21/67; H05B 1/02; H05B 3/26

(52) U.S. Cl. CPC H01L 21/67248; H05B 1/0233; H01J 37/32724; H01L 21/67103; H05B 3/265

(57) ABSTRACT

A ceramic heater includes a ceramic plate having a front surface that serves as a wafer placement surface, resistance heating elements that are embedded in the ceramic plate, a tubular shaft that supports the ceramic plate from a rear surface of the ceramic plate, and a thermocouple passage that extends from a start point in a within-shaft region of the rear surface of the ceramic plate, the within-shaft region being surrounded by the tubular shaft, to a terminal end position in an outer peripheral portion of the ceramic plate. The thermocouple passage includes a curved portion between the start point and the terminal end position.

### BACKGROUND OF THE INVENTION

### 1. Field of the Invention

The present invention relates to a ceramic heater.

### 2. Description of the Related Art

As one type of ceramic heater, there has hitherto been known the so-called two-zone heater in which resistance heating elements are embedded independently of each other in an inner peripheral side and an outer peripheral side of a disk-shaped ceramic plate having a wafer placement surface. For example, Patent Literature (PTL) 1 discloses a ceramic heater 410 illustrated in FIG. 10. In the ceramic heater 410, a temperature in an outer peripheral side of a ceramic plate 420 is measured by an outer-peripheral-side thermocouple 450. A thermocouple guide 432 extends straight through the inside of a tubular shaft 440 from a lower side toward an upper side and is then bent in an arch shape to turn 90°. The thermocouple guide 432 is attached to a slit 426a that is formed in a region of a rear surface of the ceramic plate 420, the region being surrounded by the tubular shaft 440. The slit 426a serves as an inlet portion of a thermocouple passage 426. The outer-peripheral-side thermocouple 450 is inserted into a tube of the thermocouple guide 432 and extends up to a terminal end position of the thermocouple passage 426.

### CITATION LIST

### PATENT LITERATURE

PTL 1: International Publication Pamphlet No. 2012/039453 (FIG. 11)

### SUMMARY OF THE INVENTION

However, because the thermocouple passage 426 extends straight in one direction, the thermocouple passage 426 may interfere with an obstacle inside the ceramic plate 420 depending on a position of temperature measurement. Accordingly, a degree of freedom in design for the position of the temperature measurement is restricted in some cases.

The present invention has been made with intent to solve the above-mentioned problem, and a main object of the present invention is to increase a degree of freedom in design for a position of temperature measurement.

A ceramic heater according to the present invention includes:

a ceramic plate having a front surface that serves as a wafer placement surface;

a resistance heating element that is embedded in the ceramic plate;

a tubular shaft that supports the ceramic plate from a rear surface of the ceramic plate; and

a thermocouple passage that extends from a start point in a within-shaft region of the rear surface of the ceramic plate, the within-shaft region being surrounded by the tubular shaft, to a terminal end position in an outer peripheral portion of the ceramic plate,

wherein the thermocouple passage includes a curved portion between the start point and the terminal end position.

According to the above-described ceramic heater, the thermocouple passage includes the curved portion between the start point and the terminal end position. Therefore, even when an obstacle is present inside the ceramic plate, the thermocouple passage can be disposed while avoiding the obstacle with the presence of the curved portion. As a result, a degree of freedom in design for a position of temperature measurement can be increased.

In the ceramic heater according to the present invention, the curved portion may be disposed while avoiding a predetermined location defined in the ceramic plate. The predetermined location includes, for example, a location where a hole (such as a lift pin hole or a gas hole) penetrating through the ceramic plate in a thickness direction of the ceramic plate is formed, and a location where the resistance heating element is wired.

In the ceramic heater according to the present invention, the curved portion may be curved in a planar direction of the ceramic plate. With this feature, it is easier to avoid, for example, the hole penetrating through the ceramic plate in the thickness direction of the ceramic plate.

In the ceramic heater according to the present invention, the curved portion may be curved in the thickness direction of the ceramic plate. With this feature, it is easier to avoid the resistance heating element that is embedded in the ceramic plate substantially parallel to the wafer placement surface. In this case, the terminal end position may be disposed between a plane in the ceramic plate where the resistance heating element is embedded and the wafer placement surface. With this feature, since the terminal end position, namely the position of temperature measurement, is close to the wafer placement surface, a difference between the result of the temperature measurement by a thermocouple and the surface temperature of a wafer is reduced and a more practically useful result can be obtained with the temperature measurement.

In the ceramic heater according to the present invention, preferably, the curved portion has a curvature radius of 20 mm or more. With this feature, the thermocouple can be relatively smoothly inserted into the thermocouple passage.

The ceramic heater according the present invention may further include a thermocouple that is inserted into the thermocouple passage, wherein a temperature measurement portion at a tip end of the thermocouple reaches the terminal end position.

### BRIEF DESCRIPTION OF THE DRAWINGS

FIG. 1 is a perspective view of a ceramic heater 10.

FIG. 2 is a sectional view taken along A-A in FIG. 1.

FIG. 3 is a sectional view taken along B-B in FIG. 1.

FIG. 4 is a plan view when looking at a thermocouple passage 26 from a rear surface 20b of a ceramic plate 20.

FIG. 5 is a front view of a thermocouple guide 32.

FIG. 6 is a plan view when looking at a modification of the thermocouple passage 26 from the rear surface 20b of the ceramic plate 20.

FIG. 7 is a vertical sectional view of a modification of the ceramic heater 10.

FIG. 8 is a plan view when looking at a modification of the thermocouple passage 26 from the rear surface 20b of the ceramic plate 20.

FIG. 9 is a plan view when looking at a modification of the thermocouple passage 26 from the rear surface 20b of the ceramic plate 20.

FIG. 10 is an explanatory view of a related-art ceramic heater.

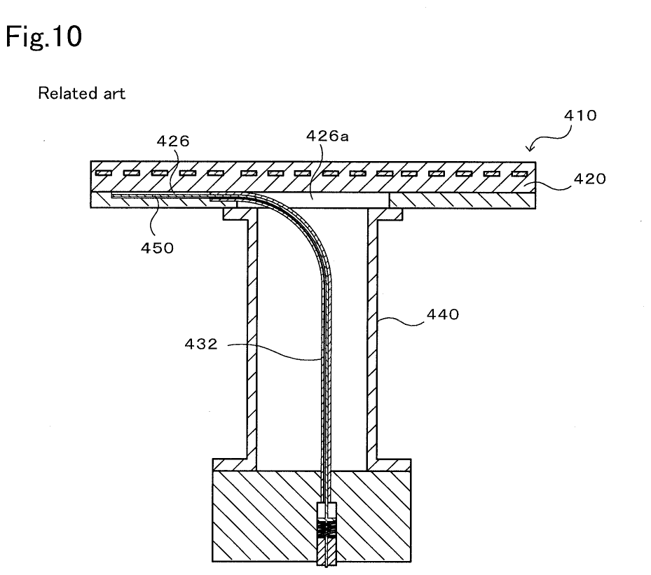

### DETAILED DESCRIPTION OF THE INVENTION

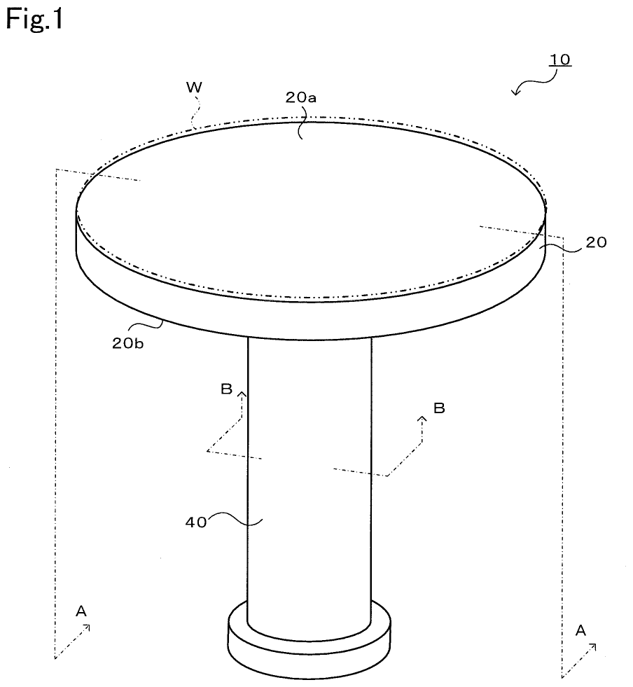

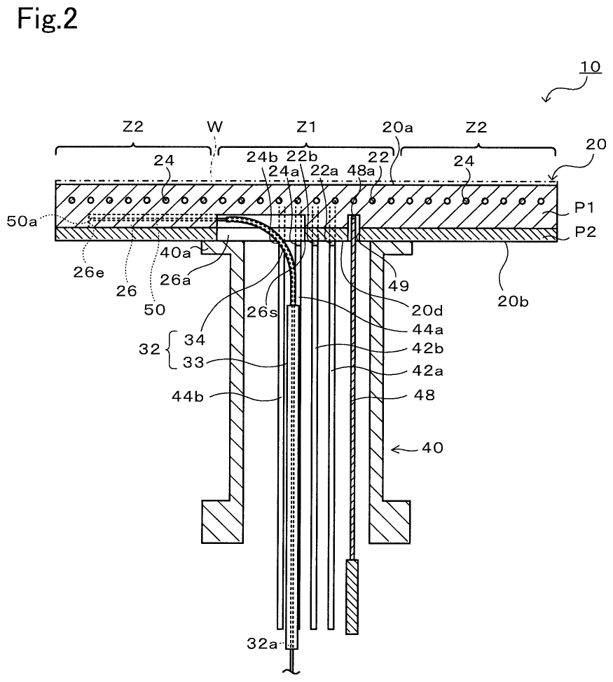

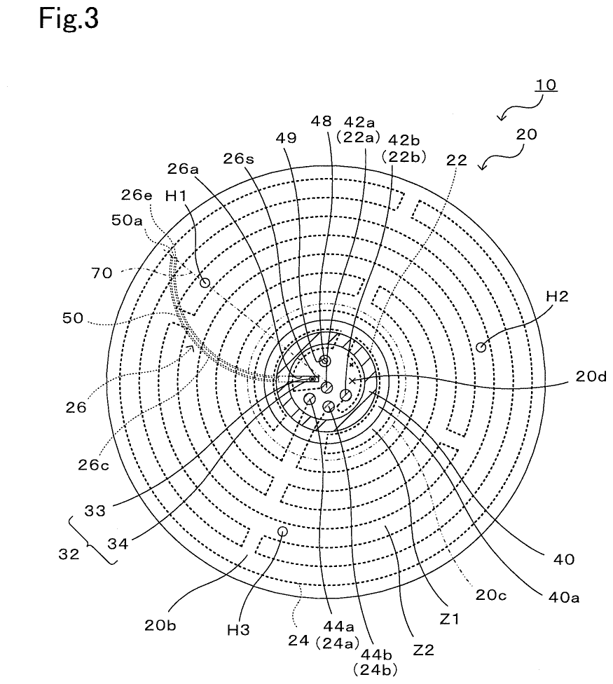

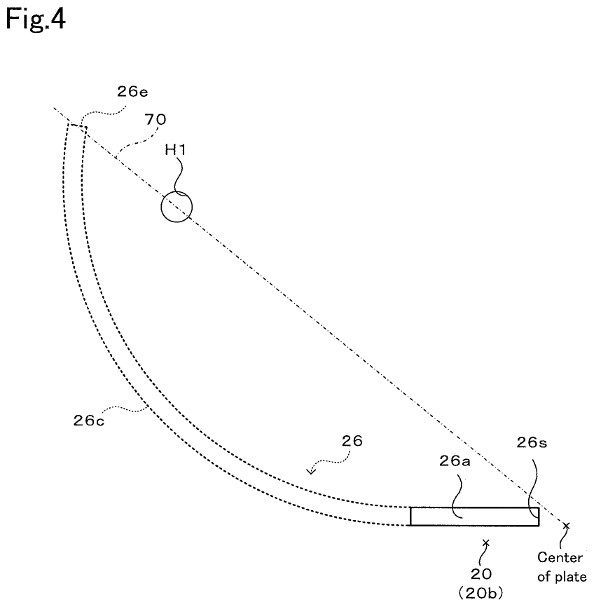

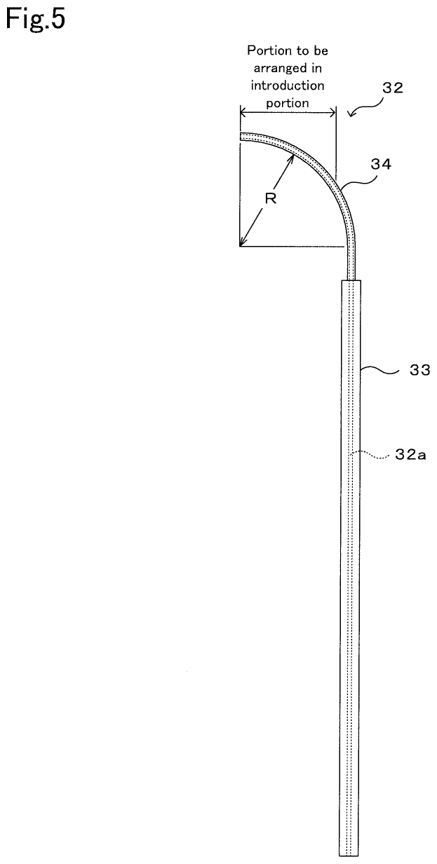

Preferred embodiments of the present invention will be described below with reference to the drawings. FIG. 1 is a perspective view of a ceramic heater 10, FIG. 2 is a sectional view taken along A-A in FIG. 1, FIG. 3 is a sectional view taken along B-B in FIG. 1, FIG. 4 is a plan view when looking at a thermocouple passage 26 from a rear surface 20b of a ceramic plate 20, FIG. 5 is a front view of a thermocouple guide 32.

The ceramic heater 10 is used to heat a wafer W on which processing, such as etching or CVD, is to be performed, and is installed within a vacuum chamber (not illustrated). The ceramic heater 10 includes a disk-shaped ceramic plate 20 having a wafer placement surface 20a, and a tubular shaft 40 that is bonded to a surface (rear surface) 20b of the ceramic plate 20 opposite to the wafer placement surface 20a.

The ceramic plate 20 is a disk-shaped plate made of a ceramic material represented by aluminum nitride or alumina. The diameter of the ceramic plate 20 is not limited to a particular value and may be about 300 mm, for example. The ceramic plate 20 is divided into an inner-peripheral-side zone Z1 of a small circular shape and an outer-peripheral-side zone Z2 of an annular shape by a virtual boundary 20c (see FIG. 3) concentric to the ceramic plate 20. An inner-peripheral-side resistance heating element 22 is embedded in the inner-peripheral-side zone Z1 of the ceramic plate 20, and an outer-peripheral-side resistance heating element 24 is embedded in the outer-peripheral-side zone Z2. The resistance heating elements 22 and 24 are each constituted by a coil containing, as a main component, molybdenum, tungsten, or tungsten carbide, for example. As illustrated in FIG. 2, the ceramic plate 20 is fabricated by surface-bonding an upper plate P1 and a lower plate P2 thinner than the upper plate P1.

The tubular shaft 40 is made of a ceramic material, such as aluminum nitride or alumina, like the ceramic plate 20. A flange portion 40a at an upper end of the tubular shaft 40 is bonded to the ceramic plate 20 by diffusion bonding.

As illustrated in FIG. 3, the inner-peripheral-side resistance heating element 22 is formed such that it starts from one of a pair of terminals 22a and 22b and reaches the other of the pair of terminals 22a and 22b after being wired in a one-stroke pattern over substantially the entirety of the inner-peripheral-side zone Z1 while being folded at a plurality of turn-around points. The pair of terminals 22a and 22b are disposed in a within-shaft region 20d (that is defined as a region of the rear surface 20b of the ceramic plate 20, the region locating within the tubular shaft 40). Power feeder rods 42a and 42b each made of a metal (for example, Ni) are bonded respectively to the pair of terminals 22a and 22b.

As illustrated in FIG. 3, the outer-peripheral-side resistance heating element 24 is formed such that it starts from one of a pair of terminals 24a and 24b and reaches the other of the pair of terminals 24a and 24b after being wired in a one-stroke pattern over substantially the entirety of the outer-peripheral-side zone Z2 while being folded at a plurality of turn-around points. The pair of terminals 24a and 24b are disposed in the within-shaft region 20d of the rear surface 20b of the ceramic plate 20. Power feeder rods 44a and 44b each made of a metal (for example, Ni) are bonded respectively to the pair of terminals 24a and 24b.

As illustrated in FIG. 3, the ceramic plate 20 has a plurality of (here, three) lift pin holes H1 to H3 penetrating through the ceramic plate 20 in a thickness direction. The three lift pin holes H1 to H3 are arranged on a circle concentric to the ceramic plate 20 at intervals of a predetermined angle (here, 120°). Lift pins (not illustrated) are vertically movably inserted into the lift pin holes H1 to H3. The lift pins are used to vertically move the wafer W relative to the wafer placement surface 20a.

Inside the ceramic plate 20, as illustrated in FIGS. 2 and 3, the thermocouple passage 26 in the form of an elongate hole into which an outer-peripheral-side thermocouple 50 is to be inserted is formed parallel to the wafer placement surface 20a. The thermocouple passage 26 extends from a start point 26s in the within-shaft region 20d of the rear surface 20b of the ceramic plate 20 to a terminal end position 26e disposed on an outer peripheral side of the ceramic plate 20. As illustrated in FIGS. 3 and 4, the terminal end position 26e is disposed on a straight line 70, which passes the lift pin hole H1 and matches the radius of the ceramic plate 20, at a location closer to an outer periphery of the ceramic plate 20 than the lift pin hole H1. An entry portion of the thermocouple passage 26 extending from the start point 26s to the flange portion 40a is an introduction portion 26a in the form of an elongate groove into which a tip end of a curved portion 34 of the thermocouple guide 32 is to be fitted. The introduction portion 26a is opened to the within-shaft region 20d. The thermocouple passage 26 includes a curved portion 26c between the start point 26s and the terminal end position 26e, the curved portion 26c being curved in a substantially C-like shape. The curved portion 26c is curved in the planar direction of the ceramic plate 20 and is disposed while avoiding the lift pin hole H1. The ceramic plate 20 is fabricated by bonding a lower plate P2 that includes the introduction portion 26a formed as a through-hole, and an upper plate P1 in which a portion of the thermocouple passage 26 except for the introduction portion 26a is formed as a curved groove.

As illustrated in FIG. 5, the thermocouple guide 32 is a tubular member made of a metal (for example, stainless) and having a guide hole 32a. The thermocouple guide 32 includes a vertical portion 33 extending in a vertical direction with respect to the wafer placement surface 20a, and a curved portion 34 extending while turning from the vertical direction to a horizontal direction. An outer diameter of the vertical portion 33 is greater than that of the curved portion 34, but an inner diameter of the vertical portion 33 is the same as that of the curved portion 34. Because the outer diameter of the curved portion 34 is relatively small as mentioned above, a width of the introduction portion 26a of the thermocouple passage 26 through which the curved portion 34 is inserted can be reduced. Alternatively, the outer diameter of the vertical portion 33 may be set to be the same as that of the curved portion 34. A curvature radius R of the curved portion 34 is not limited to a particular value and may be about 30 mm, for example. The outer-peripheral-side thermocouple 50 is inserted through the guide hole 32a of the thermocouple guide 32. The tip end of the curved portion 34 may be simply fitted into the introduction portion 26a or may be firmly held in the introduction portion 26a by joining or bonding.

Inside the tubular shaft 40, as illustrated in FIG. 2, there are arranged not only the thermocouple guide 32, but also the power feeder rods 42a and 42b connected respectively to the pair of terminals 22a and 22b of the inner-peripheral-side resistance heating element 22, and the power feeder rods 44a and 44b connected respectively to the pair of terminals 24a and 24b of the outer-peripheral-side resistance heating element 24. In addition, an inner-peripheral-side thermocouple 48 for measuring a temperature near the center of the ceramic plate 20 and the outer-peripheral-side thermocouple 50 for measuring a temperature near the outer periphery of the ceramic plate 20 are also arranged inside the tubular shaft 40. The inner-peripheral-side thermocouple 48 is inserted into a recess 49 formed in the within-shaft region 20d of the ceramic plate 20, and a temperature measurement portion 48a at a tip end of the inner-peripheral-side thermocouple 48 is held in contact with the ceramic plate 20. The recess 49 is formed at a position not interfering with the terminals 22a, 22b, 24a and 24b and the introduction portion 26a of the thermocouple passage 26. The outer-peripheral-side thermocouple 50 is a sheathed thermocouple and is arranged to pass through the guide hole 32a of the thermocouple guide 32 and the thermocouple passage 26. A temperature measurement portion 50a at a tip end of the outer-peripheral-side thermocouple 50 is arranged to pass through the thermocouple passage 26 and to come into contact with the terminal end position 26e.

An example of use of the ceramic heater 10 will be described below. First, the ceramic heater 10 is installed within a vacuum chamber (not illustrated), and the wafer W is placed on the wafer placement surface 20a of the ceramic heater 10. Then, electric power supplied to the inner-peripheral-side resistance heating element 22 is adjusted such that the temperature detected by the inner-peripheral-side thermocouple 48 is kept at a predetermined inner-peripheral-side target temperature. Furthermore, electric power supplied to the outer-peripheral-side resistance heating element 24 is adjusted such that the temperature detected by the outer-peripheral-side thermocouple 50 is kept at a predetermined outer-peripheral-side target temperature. Thus the temperature of the wafer W is controlled to be kept at a desired temperature. Thereafter, the interior of the vacuum chamber is evacuated to create a vacuum atmosphere or a pressure reduced atmosphere, plasma is generated inside the vacuum chamber, and CVD film formation or etching is performed on the wafer W by utilizing the generated plasma.

In the above-described ceramic heater 10 according to this embodiment, the thermocouple passage 26 includes the curved portion 26c between the start point 26s and the terminal end position 26e. Therefore, even when an obstacle, such as the lift pin hole H1, is present inside the ceramic plate 20, the thermocouple passage 26 can be disposed while avoiding the obstacle with the presence of the curved portion 26c. As a result, a degree of freedom in design for a position of temperature measurement by the outer-peripheral-side thermocouple 50 can be increased.

Furthermore, since the curved portion 26c is curved in the planar direction of the ceramic plate 20, it is easier to avoid the lift pin hole H1 that penetrates through the ceramic plate 20 in the thickness direction.

The terminal end position 26e of the thermocouple passage 26, namely the position of the temperature measurement by the outer-peripheral-side thermocouple 50, is disposed on an outer peripheral side with respect to the lift pin hole H1. More specifically, the terminal end position 26e is disposed on the straight line 70, which passes the lift pin hole H1 and matches the radius of the ceramic plate 20, at the location closer to the outer periphery of the ceramic plate 20 than the lift pin hole H1. Therefore, the start point 26s in the within-shaft region 20d and the terminal end position 26e cannot be connected by a straight line. Accordingly, the presence of the curved portion 26c in the thermocouple passage 26 is highly significant.

In addition, the curvature radius of the curved portion 26c is preferably 20 mm or more. Under such a condition, the outer-peripheral-side thermocouple 50 can be relatively easily inserted into the thermocouple passage 26. As a result of actually forming the thermocouple passage 26 including the curved portion 26c with the curvature radius of 20 mm and inserting the outer-peripheral-side thermocouple 50 into the thermocouple passage 26 multiple times, the outer-peripheral-side thermocouple 50 passed smoothly through the curved portion 26c in most cases. However, in some cases, the outer-peripheral-side thermocouple 50 was bent in the curved portion 26c and did not pass smoothly through the curved portion 26c. On the other hand, as a result of actually forming the thermocouple passage 26 including the curved portion 26c with the curvature radius of 30 mm and inserting the outer-peripheral-side thermocouple 50 into the thermocouple passage 26 multiple times, the outer-peripheral-side thermocouple 50 passed smoothly through the curved portion 26c in all the cases. For that reason, the curvature radius of the curved portion 26c is more preferably 30 mm or more.

It is needless to say that the present invention is not limited to the above-described embodiment and the present invention can be implemented in various forms insofar as not departing from the technical scope of the present invention.

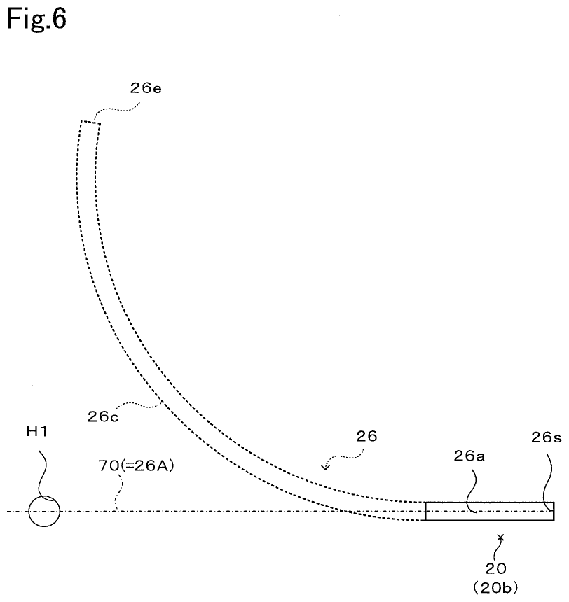

While, in the above-described embodiment, the terminal end position 26e of the thermocouple passage 26 is disposed on the outer peripheral side with respect to the lift pin hole H1, the present invention is not limited to such a particular case. For example, as illustrated in FIG. 6, the terminal end position 26e of the thermocouple passage 26 may be disposed at a location away from the straight line 70 that passes the lift pin hole H1 and matches the radius of the ceramic plate 20. In FIG. 6, the lift pin hole H1 is disposed on an axial line 26A of the introduction portion 26a in the form of an elongate hole. Here, the axial line 26A is aligned with the straight line 70. In FIG. 6, the same components as those in the above-described embodiment are denoted by the same signs. In this case, if the thermocouple passage is linearly formed along the axial line 26A of the introduction portion 26a, the thermocouple passage interferes with the lift pin hole H1. To avoid the interference with the lift pin hole H1, the thermocouple passage 26 includes the curved portion 26c.

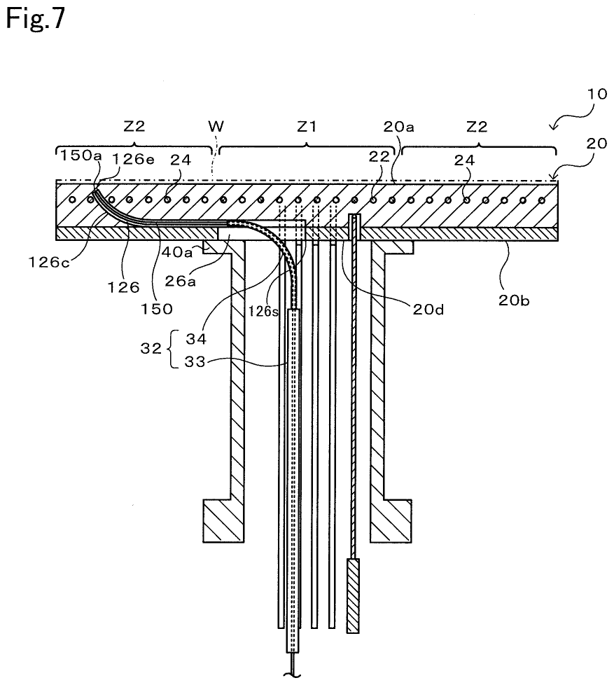

While the above embodiment has been described in connection with an example in which the curved portion 26c is curved in the planar direction of the ceramic plate 20, the present invention is not limited to such a particular case. For example, as illustrated in FIG. 7, a curved portion 126c of a thermocouple passage 126 may be disposed in shape curving in the thickness direction of the ceramic plate 20 between a start point 126s and a terminal end position 126e. The curvature radius of the curved portion 126c is preferably more than 20 mm and more preferably more than 30 mm. In FIG. 7, the terminal end position 126e of the thermocouple passage 126 is disposed between the wafer placement surface 20a and a plane in the ceramic plate 20 where the outer-peripheral-side resistance heating element 24 is embedded, and a temperature measurement portion 150a of an outer-peripheral-side thermocouple 150 is arranged to be brought into contact with the terminal end position 126e. In FIG. 7, the same components as those in the above-described embodiment are denoted by the same signs. With the above-described arrangement, the thermocouple passage 126 can easily avoid the inner-peripheral-side and outer-peripheral-side resistance heating elements 22 and 24, which are embedded in the ceramic plate 20 substantially parallel to the wafer placement surface 20a, with the presence of the curved portion 126c. Furthermore, since the terminal end position 126e (namely, the position of temperature measurement portion 150a) is close to the wafer placement surface 20a, the difference between the result of the temperature measurement by the outer-peripheral-side thermocouple 150 and the surface temperature of the wafer W is reduced and a more practically useful result can be obtained with the temperature measurement. In the above-described case, a portion of the thermocouple passage 126, the portion passing the plane where the resistance heating elements 22 and 24 are disposed, may be arranged to pass between heater regions of the multi-zone heater (namely, between the inner-peripheral-side zone Z1 and the outer-peripheral-side zone Z2). Such an arrangement can reduce the influence of the thermocouple passage 126 on the inner-peripheral-side and outer-peripheral-side resistance heating elements 22 and 24.

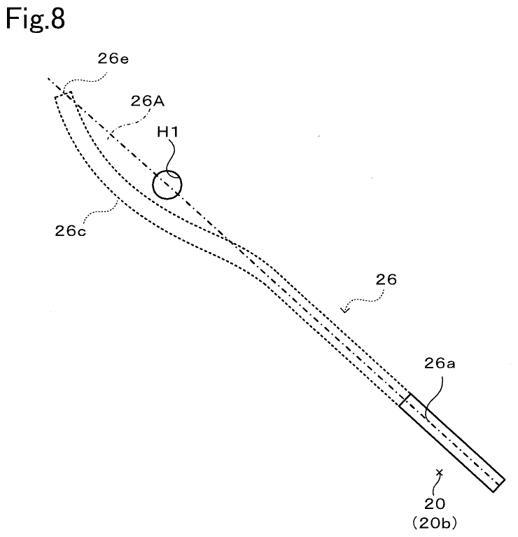

While, in the above-described embodiment, an entire region of the thermocouple passage 26 from an end of the introduction portion 26a to the terminal end position 26e is formed as the curved portion 26c, the present invention is not limited to such a particular case. For example, as illustrated in FIG. 8, a region of the thermocouple passage 26 spanning from the end of the introduction portion 26a to a location just before the lift pin hole H1 may be formed to extend along the axial line 26A of the introduction portion 26a, and only a region of the thermocouple passage 26 spanning from the location just before the lift pin hole H1 to the terminal end position 26e may be formed as the curved portion 26c of a substantially C-like shape.

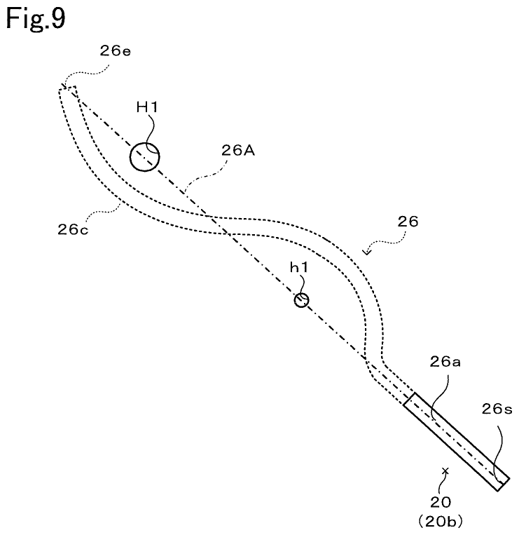

While, in the above-described embodiment, the curved portion 26c of the thermocouple passage 26 is formed in the substantially C-like shape, the present invention is not limited to such a particular case. For example, as illustrated in FIG. 9, when the lift pin hole H1 and a gas hole h1 (namely, a hole penetrating through the ceramic plate 20 in the thickness direction and used to supply He gas to a rear surface side of the wafer W) are disposed on the axial line 26A of the introduction portion 26a, the curved portion 26c may be formed in a substantially S-like shape while avoiding both the lift pin hole H1 and the gas hole h1. Moreover, the curved portion 26c may be formed in a randomly curved shape that is obtained by combining the S-like shape and the C-like shape as appropriate.

In the above-described embodiment, the thermocouple passage 26 may include a combination of the curved portion that is curved in the planar direction of the ceramic plate 20 and the curved portion that is curved in the thickness direction thereof. For example, the terminal end position (namely, the position of the temperature measurement portion) can be located close to the wafer placement surface by arranging the thermocouple passage 26 so as to avoid the lift pin hole with the presence of the curved portion that is curved in the planar direction, and to avoid the inner-peripheral-side and outer-peripheral-side resistance heating elements 22 and 24 with the presence of the curved portion that is curved in the thickness direction.

While, in the above-described embodiment, the resistance heating elements 22 and 24 are each in the form of a coil, the shape of each resistance heating element is not always limited to the coil. In another example, the resistance heating element may be a print pattern or may have a ribbon-like or mesh-like shape.

In the above-described embodiment, the ceramic plate 20 may incorporate an electrostatic electrode and/or an RF electrode in addition to the resistance heating elements 22 and 24.

While the so-called two-zone heater has been described, by way of example, in the above embodiment, the present invention is not always limited to the two-zone heater. In another example, the inner-peripheral-side zone Z1 may be divided into a plurality of inner-peripheral-side small zones, and the resistance heating element may be wired in a one-stroke pattern for each of the inner-peripheral-side small zones. Furthermore, the outer-peripheral-side zone Z2 may be divided into a plurality of outer-peripheral-side small zones, and the resistance heating element may be wired in a one-stroke pattern for each of the outer-peripheral-side small zones. Each of the inner-peripheral-side and outer-peripheral-side small zones may have an annular shape, a fan-like shape, or any other suitable shape.

While, in the above-described embodiment, the thermocouple guide 32 is attached to the introduction portion 26a of the thermocouple passage 26, it may be used as follows. The thermocouple guide 32 is placed in the introduction portion 26a when the outer-peripheral-side thermocouple 50 is inserted into the thermocouple passage 26, and after inserting the outer-peripheral-side thermocouple 50 into the thermocouple passage 26, the thermocouple guide 32 is removed. Alternatively, the outer-peripheral-side thermocouple 50 may be inserted into the thermocouple passage 26 without using the thermocouple guide 32.

In the above-described embodiment, when the thermocouple passage 26 is formed as a passage having a cross-section of a substantially rectangular shape, the boundary between one surface and another adjacent surface within the passage (for example, the boundary between a bottom surface and a side surface) is preferably formed to define a chamfered surface or a rounded surface to be free from edges.

In the above-described embodiment, an outer diameter d of the outer-peripheral-side thermocouple 50 is preferably 0.5 mm or more and 2 mm or less. If the outer diameter d is less than 0.5 mm, the outer-peripheral-side thermocouple 50 is likely to bend when it is inserted into the thermocouple passage 26, and a difficulty arises in inserting the outer-peripheral-side thermocouple 50 up to the terminal end position 26e. If the outer diameter d is more than 2 mm, the outer-peripheral-side thermocouple 50 has no flexibility, and a difficulty also arises in inserting the outer-peripheral-side thermocouple 50 up to the terminal end position 26e.

In the above-described embodiment, when the temperature measurement portion 50a of the other outer-peripheral-side thermocouple 50 has a convex surface, the thermocouple passage 26 may be formed to have, at the terminal end position 26e, a concave surface in part of a vertical wall defining a terminal end surface of the thermocouple passage 26 (part of a vertical wall at the terminal end position 26e), the part coming into contact with the temperature measurement portion 50a. In such a case, since the temperature measurement portion 50a of the other outer-peripheral-side thermocouple 50 is brought into surface contact or nearly surface contact with the concave surface, the accuracy in the temperature measurement can be improved.

The present application claims priority from Japanese Patent Application No. 2020-016116 filed Feb. 3, 2020, the entire contents of which are incorporated herein by reference.

What is claimed is:

1. A ceramic heater comprising:
a ceramic plate having a front surface that serves as a wafer placement surface;
a resistance heating element that is embedded in the ceramic plate;
a tubular shaft that supports the ceramic plate from a rear surface of the ceramic plate; and
a thermocouple passage that extends from a start point in a within-shaft region of the rear surface of the ceramic plate, the within-shaft region being surrounded by the tubular shaft, to a terminal end position in an outer peripheral portion of the ceramic plate,
wherein the thermocouple passage includes a curved portion between the start point and the terminal end position.

2. The ceramic heater according to claim 1,
wherein the curved portion is disposed while avoiding a predetermined location defined in the ceramic plate.

3. The ceramic heater according to claim 1,
wherein the curved portion is curved in a planar direction of the ceramic plate.

4. The ceramic heater according to claim 1,
wherein the curved portion is curved in a thickness direction of the ceramic plate.

5. The ceramic heater according to claim 4,
wherein the terminal end position is disposed between a plane in the ceramic plate where the resistance heating element is embedded and the wafer placement surface.

6. The ceramic heater according to claim 1,
wherein the curved portion has a curvature radius of 20 mm or more.

7. The ceramic heater according to claim 1, further comprising a thermocouple that is inserted into the thermocouple passage, wherein a temperature measurement portion at a tip end of the thermocouple reaches the terminal end position.
